(19) United States
(12) Patent Application Publication
(10) Pub. No.: US 2010/0006929 A1
(43) Pub. Date: Jan. 14, 2010

(54) SEMICONDUCTOR DEVICE AND METHOD OF MANUFACTURING THE SAME

(75) Inventor: Takayoshi Andou, Kawasaki (JP)

Correspondence Address: SUGHRUE MION, PLLC, 2100 PENNSYLVANIA AVENUE, N.W., SUITE 800, WASHINGTON, DC, 20037, US

(73) Assignee: NEC Electronics Corporation, Kawasaki (JP)

(21) Appl. No.: 12/497,051

(22) Filed: Jul. 2, 2009

(30) Foreign Application Priority Data
Jul. 8, 2008 (JP) 2008-177613

(51) Int. Cl. H01L 29/78; H01L 21/336

(52) U.S. Cl. 257/330; 438/270; 257/E29.262; 257/E21.41

(57) ABSTRACT

A semiconductor device contains a semiconductor substrate having a p-type semiconductor layer and an n-type channel layer formed thereon; gate trenches extended through the channel layer so as to reach the p-type semiconductor layer; oxide films formed over the bottom and inner wall of the gate trenches, the oxide films being formed thicker over the bottom of the gate trenches than over the inner wall; gate electrodes formed so as to fill the gate trenches; n-type regions formed at the bottom of the gate trenches, and containing arsenic as a major n-type impurity component; low concentration p-type regions formed under the n-type regions, and having a low p-type impurity concentration; and a drain electrode formed on the back surface of the substrate.

This application is based on Japanese patent application No. 2008-177613 the content of which is incorporated hereinto by reference.

### BACKGROUND

1. Technical Field

The present invention relates to a semiconductor device and a method of manufacturing the same.

2. Related Art

In recent years, trench gate has been used as a gate electrode for power devices, which is configured by a gate electrode filled in a gate trench formed in a semiconductor substrate. Vertical MOS transistors using the trench gate have been known to produce reverse capacitance between the bottom of the gate and the drain on the back side. The capacitance, causative of lowering in the switching speed of MOS transistors, have been desired to be reduced.

Japanese Laid-Open Patent Publication No. 2005-116822 describes a semiconductor device having the trench gate. The semiconductor device is formed by the procedures below. First, on an N⁺-type substrate which serves as an N⁺-type drain region, an N⁻-type drift region, a P⁻-type body region and an N⁺-type source region are formed by epitaxial growth and ion implantation. Next, a trench is formed so as to make the bottom thereof reach the N⁻-type drift region. Next, a P-type floating region is formed at the bottom of the trench, by conducting ion implantation through the bottom of the trench, followed by annealing. Next, a deposited insulating layer is formed in the trench, by depositing, and then etching, an insulating material in the trench. Next, an oxide film, which serves later as a gate insulating film, is formed over the inner wall of the trench. An electro-conductive material is then deposited over the deposited insulating layer, to thereby form the gate electrode.

It is reportedly said that the procedures successfully provide an insulated-gate semiconductor device capable of achieving both of higher voltage resistance and lower ON-resistance, and a method of readily manufacturing the same. More specifically, provision of the floating region may contribute to promote depletion of the drift region in the OFF-state. Provision of the deposited insulating layer in the trench may prevent the gate insulating film and the gate electrode from being adversely affected by any damages given on the trench portion. The device characteristics and reliability may, therefore, be suppressed from degrading. The upper end of the deposited insulating layer is located above the upper end of the floating region. By virtue of this configuration, the gate electrode and the floating region may be prevented from being opposed, and thereby the ON-resistance may reported be prevented from increasing.

Japanese Laid-Open Patent Publication No. 2007-87985 describes an insulated-gate semiconductor device having a low concentration impurity region formed in a region of an n⁻-type semiconductor layer (drain region) where the bottom portion of the trench is located, by selectively introducing a p-type impurity by ion implantation only to the bottom portion of the trench. By setting the impurity concentration of the low concentration impurity region lower than that in the n⁻-type semiconductor layer, the gate-drain capacitance C_{gd} is reportedly reducible. It is also described that this configuration may be successful in reducing the reverse capacitance Cᵣₛₛ without lowering the impurity concentration of the drain region.

However, the configuration described in Japanese Laid-Open Patent Publication No. 2007-87985, simply provided with the low concentration impurity region at the bottom portion of the trench, might be insufficient in the effect of reducing the capacitance.

On the other hand, the technique described in Japanese Laid-Open Patent Publication No. 2005-116822 is designed to form the P-type floating region in the N⁻-type drift region, so as to form the depletion layer by the P-N junction between the N⁻-type drift region and the P-type floating region. As a matter of course, the depletion layer cannot broadly expand if the impurity concentration of the N⁻-type drift region is high, but only to reduce the capacitance to an insufficient degree. A low impurity concentration of the N⁻-type drift region however elevates the drain resistance. In addition, formation of the deposited insulating film raises a need of depositing, and then etching, an insulating material in the trench, and increases the number of necessary processes.

### SUMMARY

According to the present invention, there is provided a semiconductor device including:

a substrate containing a p-type semiconductor layer, and an n-type channel layer formed over the p-type semiconductor layer;

a trench extended through the channel layer so as to reach the p-type semiconductor layer;

an oxide film formed over the bottom and inner wall of the trench, the oxide film being formed thicker over the bottom of the trench than over the inner wall of the trench;

a gate electrode formed in the trench over the oxide film so as to fill the trench;

an n-type region formed in the p-type semiconductor layer at the bottom of the trench, and containing arsenic as a major n-type impurity component;

a low concentration p-type region formed in the p-type semiconductor layer at the bottom of the trench and under the n-type region, and having a p-type impurity concentration lower than that in the other portion of the p-type semiconductor layer; and

a drain electrode formed on the back surface of the substrate.

According to the present invention, there is provided also a method of manufacturing a semiconductor device including:

forming a trench in a substrate having a p-type semiconductor layer formed in the surficial portion thereof;

introducing an n-type impurity to the bottom of the trench by ion implantation;

oxidizing the surface of the substrate to thereby form an oxide film on the inner wall of the trench, and forming an n-type region at the bottom of the trench and a low concentration p-type region having a p-type impurity concentration lower than that in the other portion of the p-type semiconductor layer, under the n-type region, all of which proceeded by annealing;

forming a gate electrode in the trench;

introducing an n-type impurity over the entire surface of the substrate by ion implantation, to thereby form an n-type channel layer in the upper portion of the p-type semiconductor layer; and

forming a drain electrode over the back surface of the substrate,

wherein the introducing an n-type impurity by ion implantation includes at least a step of introducing arsenic as the n-type impurity, and

in the forming the n-type region and the low concentration p-type region, the n-type region contains arsenic as a main n-type impurity component, and the oxide film is formed thicker over the bottom of the trench than over the inner wall of the trench.

According to this configuration, by virtue of the large thickness of the oxide film at the bottom of the gate trench, the reverse capacitance between the bottom of the gate electrode and the drain electrode formed on the back surface of the substrate can be reduced just by a portion ascribable to the oxide film. In addition, by virtue of formation of the n-type region and the low concentration p-type region in adjacent to each other at the bottom of the gate trench, the depletion layer which determines junction capacitance between the n-type region and the low concentration p-type region may spread right under the gate electrode, and thereby the reverse capacitance between the gate electrode and the drain electrode can be reduced. As a consequence, the reverse capacitance can effectively be reduced by the contribution of two these phenomena.

In addition, according to the present invention, the n-type region and the low concentration p-type region can be formed at the bottom of the gate trench, by a method only simply added with a step of introducing an impurity ion by ion implantation to the bottom of the gate trench. At the same time, the oxide film can be made thicker at the bottom of the gate trench, by virtue of accelerated oxidation contributed by arsenic contained as a major n-type impurity component in the n-type region.

Note that all arbitrary combinations of the above-described, constituents, and all conversions of expressions in the present invention among method, apparatus and so forth are effective as embodiments of the present invention.

The present invention successfully reduce the reverse capacitance of a semiconductor device having a trench gate, only by simple procedures.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view illustrating a configuration of a semiconductor device in an embodiment of the present invention;

FIG. 2 is a plan sectional view taken along line A-A′ in FIG. 1;

FIGS. 3A to 5B are sectional views illustrating procedures for manufacturing the semiconductor device in the embodiment of the present invention; and

FIGS. 6A to 7B are sectional views illustrating procedures for manufacturing the semiconductor device in another embodiment of the present invention.

### DETAILED DESCRIPTION

The invention will now be described herein with reference to illustrative embodiments. Those skilled in the art will recognize that many alternative embodiments can be accomplished using the teachings of the present invention and that the invention is not limited to the embodiment illustrated for explanatory purposes.

Embodiments of the present invention will be explained, referring to the attached drawings. Note that any similar constituents will be given with similar reference numerals in all drawings, and explanations therefor will not be repeated.

### First Embodiment

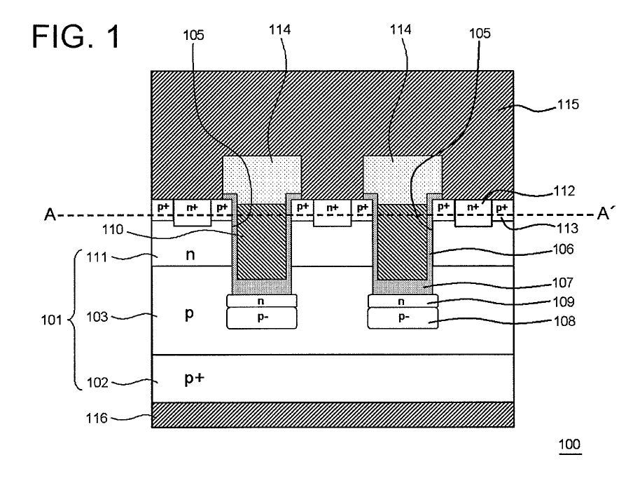

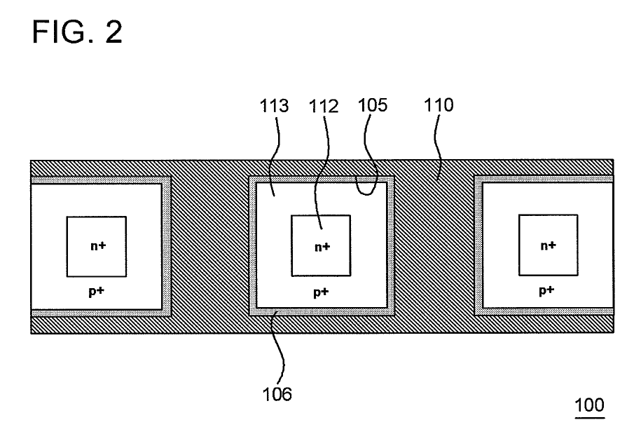

FIG. 1 is a sectional view illustrating a configuration of a semiconductor device in this embodiment, and FIG. 2 is a plan sectional view taken along line A-A′ in FIG. 1.

A semiconductor device 100 may be configured as a P-channel power MOSFET (metal-oxide-semiconductor, field-effect transistor) containing trench gates. The semiconductor device 100 contains a semiconductor substrate (substrate) 101 which is composed of a p-type (p⁺) silicon substrate 102, a p-type (p) semiconductor layer 103 formed thereon, and an n-type (n) channel layer 111 formed further thereon.

The semiconductor device 100 further contains n-type (n⁺) body regions 112 formed in the surficial portion of the channel layer 111 of the semiconductor substrate 101, and p-type (p⁺) source regions 113 totally surrounding the body regions 112 in a plan view. The semiconductor device 100 contains also gate trenches (trenches) 105 extended through the channel layer 111 so as to reach the p-type semiconductor layer 103, gate oxide films (oxide films) 106 formed over the inner wall of the gate trenches 105, thick oxide films (oxide films) 107 formed over the bottom of the gate trenches 105 and having a thickness larger than that of the gate oxide films 106, and gate electrodes 110 formed over the gate oxide films 106 and the thick oxide films 107 in the gate trenches 105, so as to fill the gate trenches 105.

The semiconductor device 100 contains still also a source electrode 115 formed over the semiconductor substrate 101, insulating interlayers 114 formed over the gate electrodes 110, and electrically isolating the gate electrodes 110 from the source electrode 115, and a drain electrode 116 formed on the back surface, which is opposite to the surface having the source electrode 115 formed thereon, of the semiconductor substrate 101, so as to be brought into contact with the silicon substrate 102.

In this embodiment, the semiconductor device 100 further contains n-type (n) regions 109 formed in the upper portion of the p-type semiconductor layer 103 under the bottom of the gate trenches 105, and containing arsenic as a main n-type impurity component, and low concentration p-type (p⁻) regions 108 formed under the n-type regions 109. The low concentration p-type regions 108 have a p-type impurity concentration lower than that in the other portion of the p-type semiconductor layer 103.

In this embodiment, the thick oxide films 107 are formed at the bottom of the gate trenches 105. Accordingly, the reverse capacitance between the bottom of the gate electrodes 110 and the drain electrode 116 on the back surface of the semiconductor substrate 101 may be reduced just by a portion ascribable to the oxide film. The thickness of the gate oxide films 106 herein may be adjusted typically to 30 nm to 60 nm or around, and the thickness of the thick oxide films 107 may be adjusted typically to 100 nm to 300 nm or around.

At the bottom of the gate trenches 105, the n-type regions 109 and the low concentration p-type regions 108 are formed in adjacent to each other. Accordingly, the depletion layers ascribable to the junction capacitance between the n-type regions 109 and the low concentration p-type regions 108 may spread right under the gate electrodes 110, and thereby the reverse capacitance between the gate electrodes 110 and the drain electrode 116 may be reduced. Since the low concentration p-type regions 108 have a p-type impurity concentration lower than that of the p-type semiconductor layer 103, so that the depletion layers can broadly spread between the n-type regions 109 and the low concentration p-type regions 108, while keeping the p-type impurity concentration of the p-type semiconductor layer 103 at a high level, and consequently keeping the drain resistance low. The thickness of the n-type regions 109 in the direction of stacking may be adjusted typically to 100 nm to 300 nm or around. The thickness of the low concentration p-type regions 108 in the direction of stacking may be adjusted typically to 300 nm to 600 nm or around.

According to the semiconductor device 100 of this embodiment, the reverse capacitance can effectively be reduced by the contribution of two these phenomena.

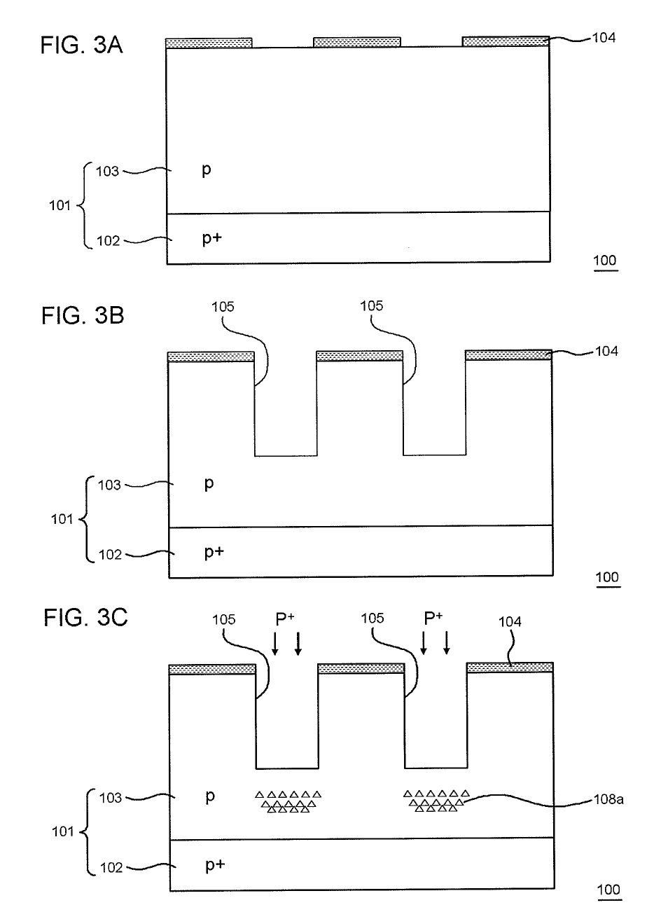

Next, procedures for manufacturing the semiconductor device 100 of this embodiment will be explained. FIGS. 3A to 5B are sectional views illustrating procedures for manufacturing the semiconductor device 100 in this embodiment.

First, the semiconductor substrate 101 is prepared. The semiconductor substrate 101 is configured to have the silicon substrate 102 and the p-type semiconductor layer 103 stacked in this order. The p-type semiconductor layer 103 herein is formed in the surficial portion of the semiconductor substrate 101.

Next, the gate trench 105 are formed in the semiconductor substrate 101 by a photolithographic technique. More specifically, a resist film 104, having openings allowing therethrough formation of the gate trenches in the semiconductor substrate 101, is formed over the semiconductor substrate 101 (FIG. 3A). Next, the gate trenches 105 are formed in the semiconductor substrate 101, by selectively etching the semiconductor substrate 101 using the resist film 104 as a mask (FIG. 3B).

Next, in order to form the future low concentration p-type regions 108, an n-type impurity 108a is introduced by ion implantation to the bottom of the gate trenches 105, while leaving the resist film 104 unremoved over the semiconductor substrate 101 (FIG. 3C). The ion species of the n-type impurity 108a herein may be phosphors (P⁺). Conditions for implantation may be determined so as to achieve a low dose not causative of inverting the conductivity type of the p-type semiconductor layer 103 after annealing (1E12 cm⁻², at an acceleration voltage of 150 keV, for example).

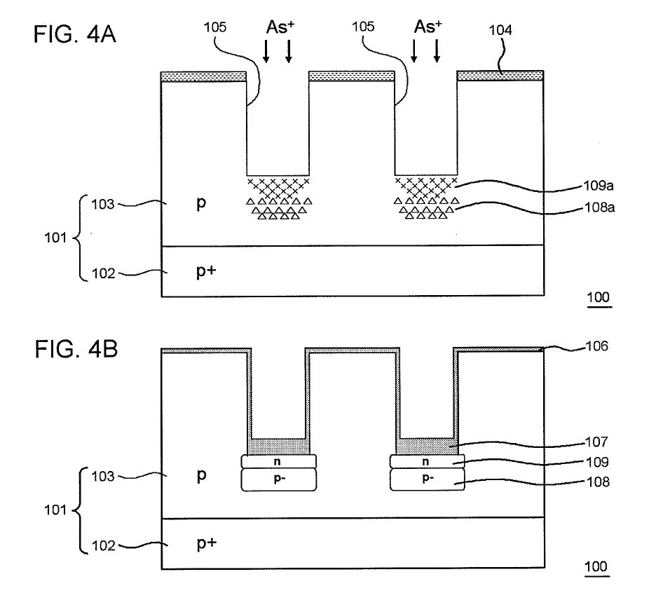

Next, in order to form the future n-type regions 109, an n-type impurity 109a is introduced by ion implantation to the bottom of the gate trenches 105, while again leaving the resist film 104 unremoved over the semiconductor substrate 101 (FIG. 4A). The ion species of the n-type impurity 109a herein may be arsenic (As⁺). Conditions for implantation may be determined so as to achieve a high dose enough to allow formation of the thick oxide films 107 at the bottom of the trenches by accelerated oxidation, at the same time when the gate oxide films 106 are formed later (5E15 cm⁻², at an acceleration voltage of 30 keV, for example).

In the process of introducing the n-type impurity 108a, phosphorus may be introduced to a depth deeper than a depth to which arsenic is introduced in the process of introducing the n-type impurity 109a. Alternatively, phosphorus may be implanted to the same depth with arsenic, since phosphorus exhibits faster diffusion speed than that of arsenic, and can thereby migrate to a larger depth.

Next, the resist film 104 is removed. The entire surface of the semiconductor substrate 101 is then subjected to thermal oxidation, to thereby form the gate oxide films 106 over the inner walls of the gate trenches 105. In this process, the n-type impurity 108a introduced into the bottom of the gate trenches 105 at a low dose diffuses into the p-type semiconductor layer 103 under annealing, to thereby form the low concentration p-type regions 108. In addition, the n-type impurity 109a introduced at a high dose diffused into the p-type semiconductor layer 103, to thereby form the n-type regions 109. In this process, the thick oxide films 107 are concomitantly formed at the bottom of the gate trenches 105, by the accelerated oxidation contributed by arsenic (FIG. 4B). By using arsenic as an n-type impurity, the oxide film at the bottom of the gate trenches 105 may be made thicker than the oxide film on the inner wall of the gate trenches 105, based on the accelerated oxidation.

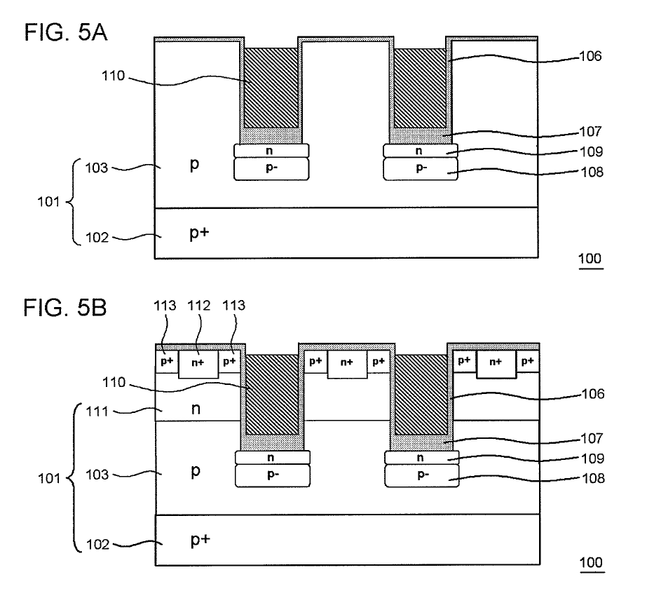

Thereafter, a polysilicon film for forming the gate electrodes 110 is deposited so as to fill the gate trenches 105. An impurity is then implanted over the entire portion of the polysilicon film. The polysilicon film is then etched back so as to remove the portion thereof exposed to the external of the gate trenches 105, to thereby form the gate electrodes 110 in the gate trenches 105 (FIG. 5A). Note that the polysilicon film herein for forming the gate electrodes 110 may be formed by depositing an impurity-containing material.

Next, an n-type impurity is introduced by ion implantation over the entire surface of the semiconductor substrate 101 so as to allow the n-type impurity to diffuse therein, to thereby form the channel layer 111 in the upper portion of the p-type semiconductor layer 103. The channel layer 111 herein may be made so as to locate the lower end thereof at a depth shallower than the bottom of the gate trenches 105. The channel layer 111 may alternatively be made before the gate trenches 105 are formed, without limiting the order of formation.

Thereafter, the body regions 112 are formed making use of a photolithographic technique, implantation of an n-type impurity and annealing. The source regions 113 are then formed making use of a photolithographic technique, implantation of a p-type impurity and annealing (FIG. 5B).

An insulating film typically composed of BPSG (Boron Phosphorus Silicate Glass) is then formed over the entire surface of the semiconductor substrate 101. The insulating film and the gate oxide films 106 are then selectively removed making use of a photolithographic technique and etching, so as to form the insulating interlayers 114 over the gate electrodes 110. Next, an aluminum film is formed by sputtering over the surface of the semiconductor substrate 101, and then patterned to form the source electrode 115. An aluminum film is formed by sputtering also on the back surface of the semiconductor substrate 101, and then patterned to form the drain electrode 116. The semiconductor device 100 as a P-channel power MOSFET illustrated in FIG. 1 may be formed by these procedures.

According to this embodiment, the n-type regions 109 and the low concentration p-type regions 108 may be formed at the bottom of the gate trenches 105, simply by a method additionally containing a step of introducing impurity ions by ion implantation to the bottom of gate trenches 105. At the same time, the oxide film may be thickened at the bottom of the gate trenches 105, based on the accelerated oxidation by the contribution of arsenic contained in the n-type regions 109. As a consequence, the reverse capacitance between the gate electrodes 110 and the drain electrode 116 may be reduced, and thereby the switching characteristics may be improved.

In addition, the low concentration p-type regions 108 in this embodiment are formed using phosphorus as the n-type impurity 108a, and the n-type regions 109 are formed using arsenic, respectively under controlled conditions for implantation, so that the low concentration p-type regions 108 and the n-type regions 109 may successfully be formed by annealing.

### Second Embodiment

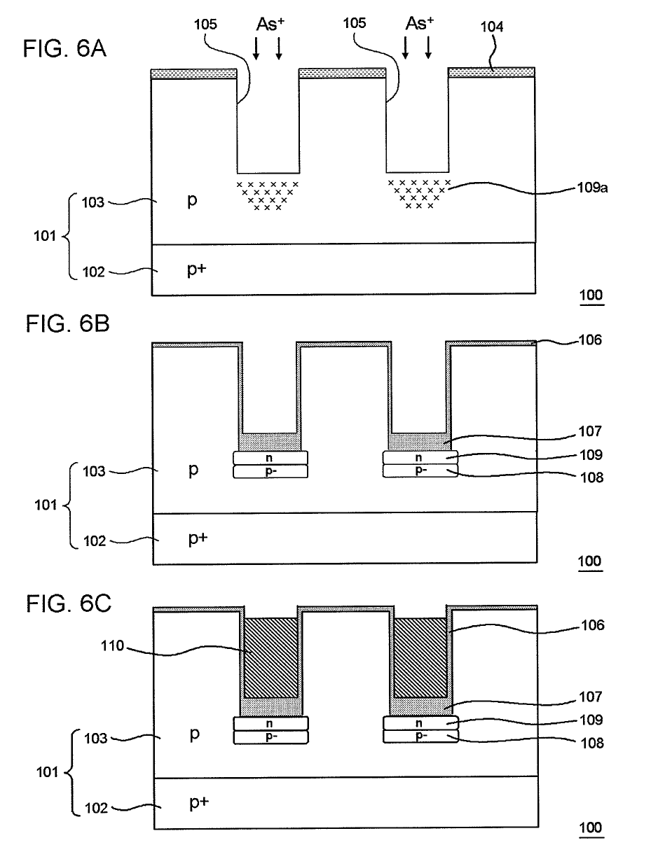

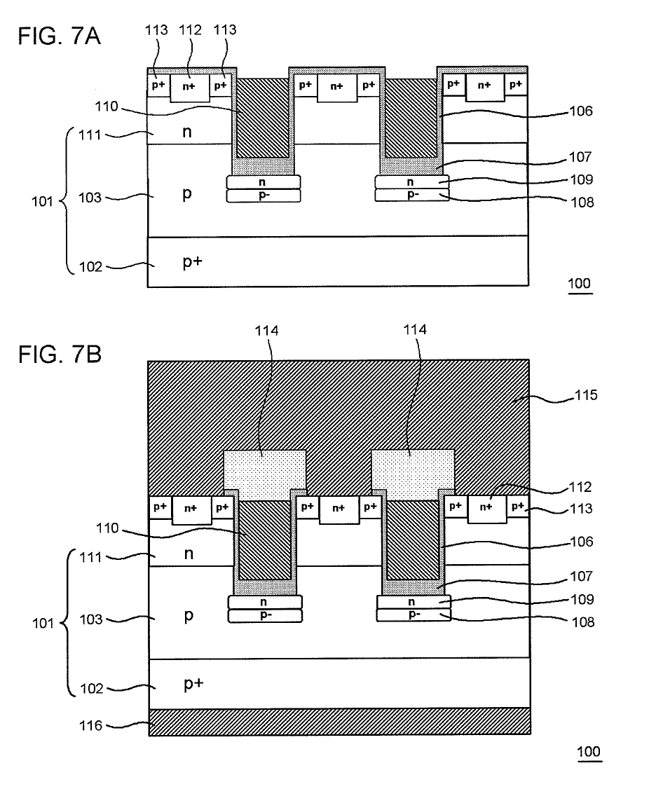

FIGS. 6A to 7B are sectional views illustrating procedures for manufacturing the semiconductor device 100 in this embodiment. This embodiment is different from First Embodiment, in that the n-type impurity is implanted only once into the bottom of the gate trenches 105.

Also in this embodiment, the gate trenches 105 are formed in the semiconductor substrate 101, by the procedures similar to those explained in the first embodiment referring to FIGS. 3A and 3B (see FIG. 3B).

Next, in order to form the future n-type regions 109 and the low concentration p-type regions 108, the n-type impurity 109a is introduced by ion implantation to the bottom of the gate trenches 105, while leaving the resist film 104 unremoved over the semiconductor substrate 101 (FIG. 6A). The ion species of the n-type impurity 109a herein may be arsenic (As⁺). Conditions for implantation may be determined so as to achieve a high dose enough to allow formation of the thick oxide films 107 at the bottom of the trenches by accelerated oxidation, at the same time when the gate oxide films 106 are formed later (5E15 cm⁻², at an acceleration voltage of 70 keV, for example).

Next, the resist film 104 is removed. The entire surface of the semiconductor substrate 101 is then subjected to thermal oxidation, to thereby form the gate oxide films 106 over the inner walls of the gate trenches 105. In this process, the n-type impurity 109a introduced into the bottom of the gate trenches 105 diffuses into the p-type semiconductor layer 103 under annealing, to thereby form the n-type regions 109 having a high concentration of the n-type impurity 109a and the low concentration p-type regions 108 having a low concentration of the n-type impurity 109a. In this process, the thick oxide films 107 are concomitantly formed at the bottom of the gate trenches 105, by the accelerated oxidation (FIG. 6B).

In this embodiment, the n-type region 109 and the low concentration p-type regions 108 may be formed, by implanting the n-type impurity 109a while setting the ion acceleration voltage higher than that in the first embodiment, so as to locate a peak of arsenic distribution at a larger depth away from the bottom of the gate trenches 105, and by carrying out the annealing at a temperature higher than that in the first embodiment, so as to allow arsenic to diffuse up to a deeper level.

Thereafter, a polysilicon film for forming the gate electrodes 110 is deposited so as to fill the gate trenches 105. An impurity is then implanted over the entire portion of the polysilicon film. The polysilicon film is then etched back so as to remove the portion thereof exposed to the external of the gate trenches 105, to thereby form the gate electrodes 110 in the gate trenches 105 (FIG. 6C). Note that the polysilicon film herein for forming the gate electrodes 110 may be formed by depositing an impurity-containing material.

Next, the channel layer 111 is formed by allowing the n-type impurity to diffuse. Thereafter, the body regions 112 are formed making use of a photolithographic technique, implantation of an n-type impurity and annealing. The source regions 113 are then formed making use of a photolithographic technique, implantation of a p-type impurity and annealing (FIG. 7A).

An insulating film typically composed of BPSG is then formed over the entire surface of the semiconductor substrate 101. The insulating film and the gate oxide films 106 are then selectively removed making use of a photolithographic technique and etching, so as to form the insulating interlayers 114 over the gate electrodes 110. Next, an aluminum film is formed by sputtering over the surface of the semiconductor substrate 101, and then patterned to form the source electrode 115. An aluminum film is formed by sputtering also on the back surface of the semiconductor substrate 101, and then patterned to form the drain electrode 116. The semiconductor device 100 of this embodiment may be formed by these procedures (FIG. 7B).

Since only once implantation of the n-type impurity to the bottom of the gate trenches 105 will suffice in this embodiment, the reverse capacitance may be reduced while decreasing the number of processes for implantation.

The embodiments of the present invention having been explained in the above referring to the drawings are merely for the purpose of exemplifying the present invention, so that also various configurations other than those described in the above may be adoptable.

It is apparent that the present invention is not limited to the above embodiment, that may be modified and changed without departing from the scope and spirit of the invention.

What is claimed is:

1. A semiconductor device comprising:
a substrate containing a p-type semiconductor layer, and an n-type channel layer formed over said p-type semiconductor layer;
a trench extended through said channel layer so as to reach said p-type semiconductor layer;
an oxide film formed over the bottom and inner wall of said trench, said oxide film being formed thicker over the bottom of said trench than over the inner wall of said trench;
a gate electrode formed in said trench over said oxide film so as to fill said trench;
an n-type region formed in said p-type semiconductor layer at the bottom of said trench, and containing arsenic as a major n-type impurity component;
a low concentration p-type region formed in said p-type semiconductor layer at the bottom of said trench and under said n-type region, and having a p-type impurity concentration lower than that in the other portion of said p-type semiconductor layer; and
a drain electrode formed on the back surface of said substrate.

2. The semiconductor device as claimed in claim 1,
wherein said low concentration p-type region contains phosphorus as a major n-type impurity component.

3. A method of manufacturing a semiconductor device comprising:
forming a trench in a substrate having a p-type semiconductor layer formed in the surficial portion thereof;
introducing an n-type impurity to the bottom of said trench by ion implantation;
oxidizing the surface of said substrate to thereby form an oxide film on the inner wall of said trench, and forming an n-type region at the bottom of said trench and a low concentration p-type region having a p-type impurity concentration lower than that in the other portion of said p-type semiconductor layer, under said n-type region, all of which proceeded by annealing;
forming a gate electrode in said trench;
introducing an n-type impurity over the entire surface of said substrate by ion implantation, to thereby form an n-type channel layer in the upper portion of said p-type semiconductor layer; and
forming a drain electrode over the back surface of said substrate,
wherein said introducing an n-type impurity by ion implantation includes at least a step of introducing arsenic as said n-type impurity, and
in said forming said n-type region and said low concentration p-type region, said n-type region contains arsenic as a main n-type impurity component, and said oxide film is formed thicker over the bottom of said trench than over the inner wall of said trench.

4. The method of manufacturing a semiconductor device as claimed in claim 3,
wherein, in said forming said n-type region and said low concentration p-type region, said oxide film is formed thicker over the bottom of said trench than over the inner wall of said trench, based on accelerated oxidation contributed by arsenic contained in said n-type region at the bottom of said trench.

5. The method of manufacturing a semiconductor device as claimed in claim 3,
wherein said introducing an n-type impurity further includes a step of introducing phosphorus as an n-type impurity, in addition to a step of introducing arsenic, and
in said forming said n-type region and said low concentration p-type region, said low concentration p-type region contains phosphorus as a major n-type impurity component.

6. The method of manufacturing a semiconductor device as claimed in claim 4,
wherein said introducing an n-type impurity further includes a step of introducing phosphorus as an n-type impurity, in addition to a step of introducing arsenic, and
in said forming said n-type region and said low concentration p-type region, said low concentration p-type region contains phosphorus as a major n-type impurity component.

7. The method of manufacturing a semiconductor device as claimed in claim 5,
wherein in said introducing an n-type impurity by ion implantation, phosphorus is introduced in said step of introducing phosphorus, to a depth deeper than a depth to which arsenic is introduced in said step of introducing arsenic.

8. The method of manufacturing a semiconductor device as claimed in claim 6,
wherein in said introducing an n-type impurity by ion implantation, phosphorus is introduced in said step of introducing phosphorus, to a depth deeper than a depth to which arsenic is introduced in said step of introducing arsenic.
